(19) United States
(12) Patent Application Publication
(10) Pub. No.: US 2021/0002779 A1
(43) Pub. Date: Jan. 7, 2021

(54) COLLECTOR PLATE

(71) Applicant: NAN YA PLASTICS CORPORATION, Taipei (TW)

(72) Inventors: SHIH-CHING LIN, Changhua County (TW); KUO-CHAO CHEN, Taoyuan City (TW)

(21) Appl. No.: 17/027,910

(22) Filed: Sep. 22, 2020

Related U.S. Application Data
(62) Division of application No. 16/283,999, filed on Feb. 25, 2019.

(30) Foreign Application Priority Data
Jun. 15, 2018 (TW) 107120751

(51) Int. Cl. C25D 1/04; H05K 1/02; H05K 9/00; H01M 4/66; H01M 10/0525; C25D 3/38; H01M 4/70

(52) U.S. Cl. CPC C25D 1/04; H05K 1/0218; H05K 9/0084; H01M 4/661; H05K 2201/0317; C25D 3/38; H01M 4/70; H05K 2201/0341; H01M 10/0525

(57) ABSTRACT

The present invention provides a collector plate including a porous ultra-thin copper foil made by the method for manufacturing porous ultra-thin copper foil. One of surfaces of the porous ultra-thin copper foil has a plurality of pores and the thickness of the porous ultra-thin copper foil is between 1 and 5 micron.

### CROSS-REFERENCE TO RELATED PATENT APPLICATION

This application is a divisional application of Ser. No. 16/283,999 filed on Feb. 25, 2019, and entitled “ULTRA-THIN COPPER FOIL STRUCTURE, COLLECTOR PLATE, ELECTROMAGNETIC INTERFERENCE SHIELD, COPPER CLAD LAMINATE AND PRINTED CIRCUIT BOARD, AND METHOD FOR MANUFACTURING POROUS ULTRA-THIN COPPER FOIL”, now pending, the entire disclosures of which are incorporated herein by reference.

### FIELD OF THE DISCLOSURE

The present disclosure relates to a collector plate including a copper foil, and more particularly to a collector plate for a lithium ion battery.

### BACKGROUND OF THE DISCLOSURE

Generally, electrical equipment and electronic products may generate electromagnetic radiations in use, and electromagnetic radiations can interfere with normal operation of other electronic devices and electronic products, and even affect human health. Therefore, in the past two decades, countries in the world's major economies have legislated that electromagnetic radiations generated by any product must comply with the regulatory standards for electromagnetic interference.

In recent years, functions of modern electronic products have become more and more diversified, and circuit design thereof have become more and more compact and complicated, hence the problem of electromagnetic interference has become one of the major challenges in product design. Furthermore, with the rising popularity of automotive electronic communication devices, a variety of electronic products are often concentrated in a small space, which can generate electromagnetic interference among each other and cause driving hazards.

In the related art, it has been disclosed that a porous ultra-thin copper foil can be used in batteries. The porous ultra-thin copper foil can reduce the fuel consumption of a car by reducing the weight of the car, and can perform pre-doping of ions effectively through its pores.

Japanese Patent No. 4762368 discloses that a porous metal foil is composed of a two dimensional network structure composed of metal fibers. It can be observed from the FE-SEM figure of said Japanese patent that the pore size of the porous metal foil made by the disclosed method is not uniform. For instance, in the related art, a specific material such as polymer coating is coated on part of a surface of a carrier layer, and then electroplating is performed on the surface. In this way, the part covered by the specific material will not form a copper coating, so that copper foils with pores can be manufactured. However, certain issues in the method mentioned above still leave room for improvement in the related art.

As a result, there is still a need to provide a porous ultra-thin copper foil having a uniform pore size, and an improved method of manufacturing the porous ultra-thin copper foil.

### SUMMARY OF THE DISCLOSURE

In response to the above-referenced technical inadequacies, the present disclosure provides an ultra-thin copper foil structure, a method for manufacturing porous ultra-thin copper foil, and a collector plate. The ultra-thin copper foil structure is manufactured by specifically ultra-thin copper foil structure, so as to improve product performance and reduce manufacturing costs.

In one aspect, the present disclosure provides an ultra-thin copper foil structure including a carrier layer, a separation layer, and an ultra-thin copper layer. The carrier layer has a predetermined surface. The separation layer is formed on the predetermined surface of the carrier layer. The ultra-thin copper layer is disposed on the carrier layer through the separation layer. The separation layer includes at least two of nickel, molybdenum, chromium, and their salts.

In certain embodiments, the ultra-thin copper foil structure further includes an intermediate copper layer disposed between the separation layer and the ultra-thin copper layer.

In one aspect, the present disclosure provides a method for manufacturing porous ultra-thin copper foil. The method for manufacturing porous ultra-thin copper foil includes: form a separation layer on a predetermined surface of a carrier layer by electroplating; form an ultra-thin copper layer on the separation layer by electroplating, the ultra-thin copper layer disposed on the carrier layer through the separation layer; and peel the carrier layer and the separation layer from the ultra-thin copper layer, and part of the ultra-thin copper layer being peeled along with the separation layer to form an ultra-thin copper foil having a plurality of pores.

In certain embodiments, the separation layer includes at least two of nickel, molybdenum, chromium, and their salts.

In certain embodiments, the step of forming separation layer further includes using a first plating solution to electroplate, and the first plating solution includes 0.1 to 5 g/L of nickel, 0.1 to 3 g/L of molybdenum, and 50 to 300 g/L of a chelating agent.

In certain embodiments, the current density used for electroplating in the step of forming separation layer is between 10 and 30 A/dm².

In certain embodiments, the method further includes forming an intermediate copper layer by electroplating on the separation layer by electroplating before forming the ultra-thin copper layer. The intermediate copper layer is disposed between the separation layer and the ultra-thin copper layer.

In certain embodiments, the step of forming the intermediate copper layer further includes using a second plating solution to electroplate, and the second plating solution includes 10 to 40 g/L of copper and 250 to 750 g/L of a chelating agent.

In certain embodiments, the current density used for electroplating in the step of forming intermediate copper layer is between 0.5 and 10 A/dm².

In certain embodiments, the method further includes forming a heat resistant layer on a surface of the ultra-thin copper layer after the step of forming the ultra-thin copper layer. The heat resistant layer is made by electroplating with current density between 0.4 and 2.5 A/dm² in a first electrolyte, and the first electrolyte includes 1 to 4 g/L of zinc, and 0.3 to 2 g/L of nickel.

In certain embodiments, the method further includes forming an antioxidant layer on a surface of the ultra-thin copper layer after the step of forming the ultra-thin copper layer. The antioxidant layer is made by electroplating with current density between 0.3 and 3 A/dm² in a second electrolyte, and the second electrolyte includes 1 to 4 g/L of chromium oxide, and 5 to 20 g/L of sodium hydroxide.

In certain embodiments, the method further includes disposing an auxiliary layer on a surface of the ultra-thin copper layer after the step of forming the ultra-thin copper layer. The auxiliary layer is made by an auxiliary solution including 0.3 to 1.5 wt % of a silane coupling agent and residual solvent.

In one aspect, the present disclosure provides a collector plate including a porous ultra-thin copper foil made by the method for manufacturing porous ultra-thin copper foil. One of surfaces of the porous ultra-thin copper foil has a plurality of pores and the thickness of the porous ultra-thin copper foil is between 1 and 5 micron.

In certain embodiments, the porosity of the porous ultra-thin copper foil is between 10 and 90%.

Therefore, by the design of the separation layer, that is the features of “the separation layer including at least two of nickel, molybdenum, chromium, and their salts” and “peel the carrier layer and the separation layer from the ultra-thin copper layer, and part of the ultra-thin copper layer being peeled along with the separation layer to form an ultra-thin copper foil having a plurality of pores”, the pore size uniformity of porous ultra-thin copper foil can be improved and manufacturing costs can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1 is a cross-sectional view according to an embodiment of the present disclosure, illustrating an ultra-thin copper foil structure;

FIG. 2 is a schematic view according to the embodiment of the present disclosure, illustrating a step S104 of a method for manufacturing porous ultra-thin copper foil; and

FIG. 3 is flowchart according to the embodiment of the present disclosure, illustrating the method for manufacturing porous ultra-thin copper foil.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

Referring to FIG. 1, FIG. 1 is a cross-sectional view according to an embodiment of the present disclosure, illustrating an ultra-thin copper foil structure. Specifically, one technique feature of the present disclosure is using a specific-structured ultra-thin copper foil structure S, shown in FIG. 1, to manufacture a porous ultra-thin copper foil.

As shown in FIG. 1, the ultra-thin copper foil structure provided by the embodiment of the present disclosure includes a carrier layer 1, separation layer 2, and an ultra-thin copper layer 4. The carrier layer has a predetermined surface 11, and the separation layer 2 is formed on the predetermined surface 11. Further, the ultra-thin copper layer 4 is disposed on the carrier layer 1 through the separation layer 2.

In detail, the carrier layer 1 is used as a support structure for carrying different material layers in the manufacturing process of the porous ultra-thin copper foil. For instance, the carrier layer 1 can be a substrate used in electroplating. The carrier layer 1 is not limited to specific sizes and types in the present disclosure. For instance, the carrier layer 1 can be made of epoxy resin, phenolic resin, polyamine formaldehyde, polysiloxanes and Teflon, etc. and can be made of other materials, such as glass fiber fabric.

In accordance with the above, in the embodiment of the present disclosure the separation layer 2 can include at least two of nickel, molybdenum, chromium, and salts thereof. In fact, the separation layer 2 can be a metal layer formed on the carrier layer 1 by electroplating, and the metal layer includes any combination of the above metals and salts thereof. For instance, the separation layer 2 can contain nickel and molybdenum. The detail of forming the separation layer 2 by electroplating will be described later in the description of manufacturing the porous ultra-thin copper foil.

Next, refer to FIG. 1. The ultra-thin copper layer 4 is disposed on the carrier layer 1 through the separation layer 2. For instance, the ultra-thin copper layer 4 is formed on the separation layer 2 by electroplating, and the separation layer 2 is disposed between the carrier layer 1 and the ultra-thin copper layer 4. Similarly, the process of manufacturing the ultra-thin copper layer 4 will be described later in the description of manufacturing the porous ultra-thin copper foil.

In addition to this, as shown in FIG. 1, the ultra-thin copper structure S provided by the embodiment of the present disclosure can further includes an intermediate copper layer 3. The intermediate copper layer 3 is disposed between the separation layer 2 and the ultra-thin copper layer 4. Specifically, the intermediate copper layer 3 can be formed on the separation layer 2 by electroplating copper, and then the ultra-thin copper layer 4 is also formed on the intermediate copper layer 3 by electroplating copper. Through disposing the intermediate copper layer 3, the separation layer 2 can be protected to prevent the plating solution for forming the ultra-thin copper layer 4 from directly contacting the separation layer 2 and corroding the separation layer 2.

It is worth mentioning that, the plating solution for forming the intermediate copper layer 3 can have different composition from the plating solution for forming the ultra-thin copper layer 4. Similarly, the detail of manufacturing the intermediate copper layer 3 will be described later in the description of manufacturing the porous ultra-thin copper foil.

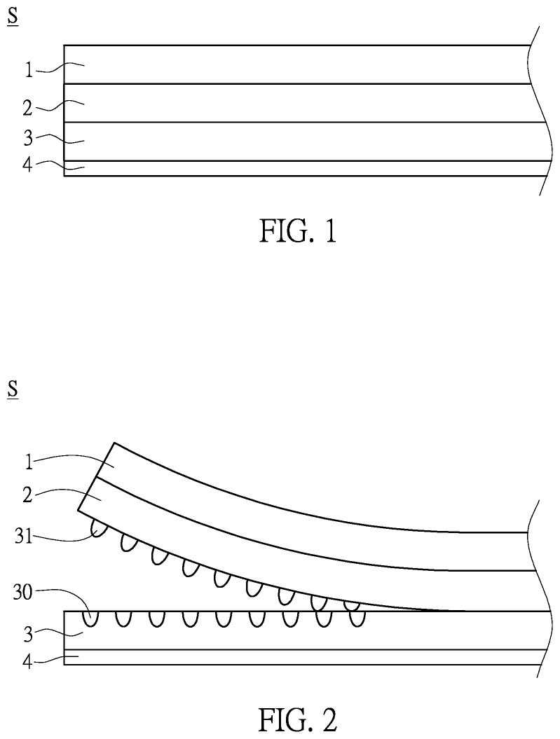

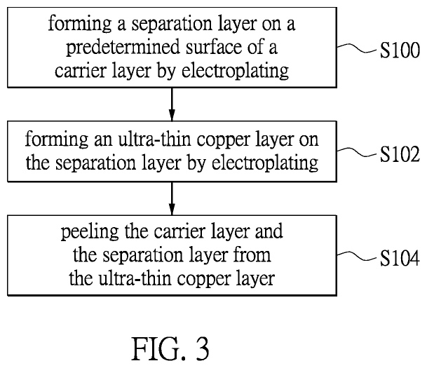

Next, refer to FIG. 2 and FIG. 3. FIG. 2 is a schematic view according to the embodiment of the present disclosure, illustrating a step S104 of a method for manufacturing porous ultra-thin copper foil. FIG. 3 is flowchart according to the embodiment of the present disclosure, illustrating the method for manufacturing porous ultra-thin copper foil. Referring to FIG. 3 first, the method for manufacturing porous ultra-thin copper foil includes at least following steps: form a separation layer on a surface of a carrier layer by electroplating (step S100); form an ultra-thin copper layer on the separation layer by electroplating (step S102); and peel the carrier layer and the separation layer from the ultra-thin copper layer (step S104).

In detail, in the step S100, the separation layer is formed on a predetermined surface 11 of the carrier layer 1 by electroplating. Specifically, the carrier layer 1 is a sheet-shaped or a plate-shaped substrate, and the predetermined surface 11 is one of the opposite surfaces of the substrate. As described in the foregoing description of the ultra-thin copper structure S provided by the embodiment of the present disclosure, the separation layer 2 includes at least two of nickel, molybdenum, chromium, and their salts.

In fact, in the embodiment of the present disclosure, through controlling the composition of the separation layer 2, the electrical property of the separation layer 2 can be adjusted, such as the current density passing the separation layer 2 and the adhesion of the separation layer 2 for the ultra-thin copper layer 4. By this controlling, in the subsequent steps (e.g., step S104) the separation layer 2 is contributed to forming uniform-sized pores and allows the pores to be evenly distributed on the surface of the ultra-thin copper foil.

For instance, the step of forming separation layer 2 further includes using a first plating solution to electroplate. For example, the first plating solution includes 0.1 to 5 g/L of nickel, 0.1 to 3 g/L of molybdenum, and 50 to 300 g/L of a chelating agent. In other words, one implementation of the present embodiment, nickel and molybdenum are used as metal materials together and cooperated with the chelating agent to form the separation layer 2 by electroplating. In the present embodiment, the chelating agent is potassium pyrophosphate, but is not limited thereto. Furthermore, in the step S100, the current density for electroplating is between 10 and 30 A/dm².

In fact, in the step of forming separation layer 2, the composition of the first plating solution for electroplating can be adjusted. For instance, different combinations of metals and chelating agents can be used to form the separation layer 2 according to the target product that is the design and requirements of porous ultra-thin copper foil. Furthermore, the current density being used in electroplating with first plating solution can be adjusted.

Subsequently, the method for manufacturing porous ultra-thin copper foil provided by the present disclosure may further includes step S102: form an intermediate copper layer 3 on the separation layer 2 by electroplating. Specifically, after the separation layer 2 formed on the carrier layer 1, the intermediate copper layer 3 is formed on the separation layer 2 first, and then conducting the step of forming ultra-thin copper layer 4.

Specifically, the intermediate layer 3 is formed between the separation layer 2 and the ultra-thin copper layer 4. As described before, the configuration of the intermediate copper layer 3 can prevent the separation layer 2 from corroding by the plating solution for forming the ultra-thin copper layer 4 and decreases the adhesion to the ultra-thin copper layer 4 (and also the intermediate copper layer 3) when subsequently forming the ultra-thin copper layer 4 on the carrier layer 1 and the separation layer 2. In this way, the effect of forming the ultra-thin copper foil through the ultra-thin copper foil structure S can be ensured. In fact, the plating solution for ultra-thin copper 4 is an acid solution, so that the metal material, such as alloy, in the separation layer 2 may be corroded.

Specifically, the step of forming intermediate copper layer 3 further includes using a second plating solution to electroplate, and the second plating solution includes 10 to 40 g/L of copper and 250 to 750 g/L of a chelating agent. In this step, potassium pyrophosphate can also be used as the chelating agent. In fact, the composition of the second plating solution for forming the intermediate copper layer 3 can be different from that of plating solution for forming the ultra-thin copper layer 4. In the step of forming the intermediate copper layer 3, the current density used is between 0.5 and 10 A/dm².

After forming the separation layer 2 or forming the separation layer 2 and the intermediate copper layer 3, the step S102 is carried out: form an ultra-thin copper layer 4 on the separation layer 2 by electroplating. After the ultra-thin copper layer 4 formed, the separation layer 2 and the intermediate copper layer 3 are disposed between the carrier layer 1 and the ultra-thin copper layer 4, and the intermediate copper layer 3 is disposed between the separation layer 2 and the ultra-thin copper layer 4.

In the embodiment of the present disclosure, the plating solution composition for forming the ultra-thin copper layer 4 can be selected and adjusted by persons skilled in the art, and is not limited thereto. For instance, acidic plating solution can be used to carry out copper electroplating process.

Finally, after forming the ultra-thin copper layer 4, which is forming the ultra-thin copper foil structure S provided by the embodiment of the disclosure, the step S104 is carried out: peeling the carrier layer 1 and the separation layer 2 from the ultra-thin copper layer 4. In fact, the step of peeling the carrier layer 1 and the separation layer 2 from the ultra-thin copper layer 4 makes a part of the ultra-thin copper layer 4 peeled along with the separation layer 2 to form an ultra-thin copper foil having a plurality of pores.

Specifically, through disposing the separation layer 2 between the ultra-thin copper layer 4 and the carrier layer 1, so that part of the material of the ultra-thin copper layer 4 interacts with the separation layer 2 and adheres thereto, and the part of the material of the ultra-thin copper layer 4 is separated from the ultra-thin copper layer 4 in the step S104. In this way, a plurality of pores are formed on the ultra-thin copper layer 4 and the ultra-thin copper layer 4 to form a porous ultra-thin copper foil. In addition, since some implementations of the present embodiment further provide an intermediate copper layer 3 disposed between the separation layer 2 and the ultra-thin copper layer 4, so that in the step S104 part 31 of the intermediate copper layer 3 can be removed along with the separation layer 2 and the other part of the intermediate copper layer 3 is disposed on the ultra-thin copper layer 4 to turn into part of the product. It is worth mention that, the porous ultra-thin copper foil structure S provided by the present embodiment and the porous ultra-thin copper foil made by the method of the present disclosure have thickness between 1.0 to 5.0 micron. In fact, since the porous ultra-thin copper foil is made by the specific step which is removing the carrier layer and the separation layer 2, it is much easier to obtain an ultra-thin copper foil by a relatively simple manufacturing method, and the manufacturing cost can be reduced. Furthermore, the ultra-thin copper foil structure S and the porous ultra-thin copper foil made by the method provided by the present embodiment have the porosity between 10 and 90%.

Furthermore, the method for manufacturing porous ultra-thin copper foil of the present embodiment can further include: form a heat resistant layer on a surface of the ultra-thin copper layer 4. Specifically, the heat resistant layer is formed on a surface opposite to the surface having the pores of the ultra-thin copper layer 4. In the step of forming the heat resistant layer, the heat resistant layer is made by electroplating in a first electrolyte which includes 1 to 4 g/L of zinc, and 0.3 to 2 g/L of nickel. The current density for forming the heat resistant layer by electroplating is between 0.4 and 2.5 A/dm². The porous ultra-thin copper foil can give products including the porous ultra-thin copper foil the function of heat resistant.

Furthermore, the method for manufacturing porous ultra-thin copper foil of the present embodiment can further include: form an antioxidant layer on a surface of the ultra-thin copper layer 4. Similarly, the antioxidant layer is formed on the surface opposite to the surface having the pores of the ultra-thin copper layer 4. In the present embodiment of the disclosure, the antioxidant layer can be made by a second electrolyte including 1 to 4 g/L of chromium oxide and 5 to 20 g/L of sodium hydroxide. The antioxidant layer can be made by electroplating with current density between 0.3 and 3 A/dm². As the heat resistant layer, disposing the antioxidant layer can also give products another function to improve their efficacy.

Another implementation of the present embodiment, the method for manufacturing porous ultra-thin copper foil can further include: dispose an auxiliary layer on a surface of the ultra-thin copper layer 4. Similarly, the auxiliary layer is formed on the surface opposite to the surface having the pores of the ultra-thin copper layer 4. The auxiliary layer can be made by an auxiliary solution, and the auxiliary solution includes 0.3 to 1.5 wt % of a silane coupling agent and residual solvent. Kinds of a silane coupling agent and solvent are not limited. For instance, the silane coupling agent, being beneficial to connect the ultra-thin copper foil with resin in the following processing steps, can be selected. The solvent is a compound that can dissolve the coupling agent.

It is worth mentioned that, the functional structure, including the heat resistant layer, the antioxidant layer, and the auxiliary layer, is selectively disposed on the ultra-thin copper layer 4. The heat resistant layer, the antioxidant layer, and the auxiliary layer can be used solely or in combination to give products different functions.

The ultra-thin copper foil made by the method of the present disclosure can be used as electronic components, such as a collector plate for manufacturing a negative electrode of a lithium battery or electromagnetic interference shielding (EMI shielding). As a result, the present disclosure provides a collector plate including the porous ultra-thin copper foil made by the foregoing manufacturing method. One of surfaces of the porous ultra-thin copper foil has a plurality of pores, and the thickness of the porous ultra-thin copper foil is between 1.0 and 5.0 micron.

Furthermore, as described above, the porosity of the porous ultra-thin copper foil is between 10 and 90%. In the present disclosure, the porosity is defined as the ratio of the surface area of the pores to the total surface area of the porous ultra-thin copper foil. Through adjusting the manufacturing method and the materials of the separation layer 2 of the ultra-thin copper foil structure S, the porosity can be adjusted to meet product requirements. For instance, decreasing the porosity of the porous ultra-thin copper foil can have better shielding effect, so that the porous ultra-thin copper foil is suitable for electromagnetic interference products.

In conclusion, by the features of “the separation layer 2 including at least two of nickel, molybdenum, chromium, and their salts” and “peel the carrier layer 1 and the separation layer 2 from the ultra-thin copper layer 4, and part of the ultra-thin copper layer 4 being peeled along with the separation layer 2 to form an ultra-thin copper foil having a plurality of pores”, the ultra-thin copper foil structure S and the method for manufacturing the porous ultra-thin copper foil provided by the disclosure can improve the pore size uniformity of porous ultra-thin copper foil and manufacturing costs can be reduced.

Further, the porosity of the porous ultra-thin copper foil can be adjusted by adjusting the manufacturing method and the materials used in the separation layer 2 of the ultra-thin copper foil structure S, so that the porous ultra-thin copper foil is suitable for different products.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A collector plate for lithium ion battery, comprising a porous ultra-thin copper foil, wherein one of surfaces of the porous ultra-thin copper foil has a plurality of pores, and the thickness of the porous ultra-thin copper foil is between 1 and 9 micron.

2. The collector plate according to claim 1, wherein the porosity of the porous ultra-thin copper foil is between 10 and 90%.
